(19) United States
(12) Patent Application Publication
(10) Pub. No.: US 2026/0301850 A1
(43) Pub. Date: Oct. 1, 2026

(54) MEMORY DEVICES, DRIVING METHODS THEREOF, AND MEMORY SYSTEMS

(71) Applicant: Yangtze Memory Technologies Co., Ltd., Wuhan (CN)

(72) Inventor: Chong Jin, Wuhan (CN)

(21) Appl. No.: 19/338,840

(22) Filed: Sep. 24, 2025

(30) Foreign Application Priority Data
Apr. 1, 2025 (CN) 202510403128.0

(51) Int. Cl. G11C 29/00; G11C 11/4093

(52) U.S. Cl. CPC G11C 29/76; G11C 11/4093; G11C 29/702

(57) ABSTRACT

Implementations of the present disclosure disclose a memory device, a driving method thereof and a memory system. A memory cell array in a memory device includes a plurality of memory banks. A peripheral circuit is coupled to the plurality of memory banks. The peripheral circuit includes a first memory circuit and a plurality of second memory circuits. The first memory circuit is configured to store address information of a damaged word line of the word lines coupled with the plurality of memory banks. The plurality of second memory circuits are all coupled with the first memory circuit, and one of the second memory circuits is configured to acquire information in the first memory circuit; and is configured to be coupled to a redundant word line corresponding to the damaged word line in response to a first control signal.

### CROSS-REFERENCE TO RELATED APPLICATION

This application claims priority to and the benefit of Chinese Patent Application 202510403128.0, filed on Apr. 1, 2025, which is hereby incorporated by reference in its entirety.

### TECHNICAL FIELD

Implementations of the present disclosure relate to semiconductor technology, and relate to, but are not limited to, memory devices, driving methods thereof, and memory systems.

### BACKGROUND

A memory device comprises a memory cell array and a peripheral circuit comprising a plurality of integrated circuit structures with different functions. The plurality of integrated circuit structures are distributed within different spatial regions of the memory device. The distribution positions of the plurality of integrated circuit structures are related to the effects of their functional implementation and product structure performance.

### BRIEF DESCRIPTION OF THE DRAWINGS

In the drawings, like reference numbers may describe similar components in different views. Like reference numbers with different letter suffixes may represent different examples of similar components. The drawings generally illustrate various implementations discussed herein by way of example and not limitation.

FIG. 1 is a first structural schematic diagram of a memory device according to an example of the present disclosure.

FIG. 2 is a first schematic diagram of a layout relationship between different structures of a memory cell array and a peripheral circuit of a memory device according to an example of the present disclosure.

FIG. 3 is a second schematic diagram of a layout relationship between different structures of a memory cell array and a peripheral circuit of a memory device according to an example of the present disclosure.

FIG. 4 is a second structural schematic diagram of a memory device according to an example of the present disclosure.

FIG. 5 is a first structural schematic diagram of a memory bank according to an example of the present disclosure.

FIG. 6 is a second structural schematic diagram of a memory bank according to an example of the present disclosure.

FIG. 7 is a first structural schematic diagram of a second memory circuit according to an example of the present disclosure.

FIG. 8 is a second structural schematic diagram of a second memory circuit according to an example of the present disclosure.

FIG. 9A is a first data information type of a damaged word line and a redundant word line according to an example of the present disclosure.

FIG. 9B is a second data information type of a damaged word line and a redundant word line according to an example of the present disclosure.

FIG. 10 is a third schematic diagram of a layout relationship between different structures of a memory cell array and a peripheral circuit of a memory device according to an example of the present disclosure.

FIG. 11 is a structural schematic diagram of a first memory circuit and a second memory circuit according to an example of the present disclosure.

FIG. 12 is a third structural schematic diagram of a memory device according to an example of the present disclosure.

FIG. 13 is a fourth structural schematic diagram of a memory device according to an example of the present disclosure.

FIG. 14 is a first structural schematic diagram of a memory system according to an example of the present disclosure.

FIG. 15 is a first structural schematic diagram of an electronic system according to an example of the present disclosure.

FIG. 16 is a second structural schematic diagram of an electronic system according to an example of the present disclosure.

FIG. 17 is a first schematic flowchart of a driving method of a memory device according to an example of the present disclosure.

FIG. 18 is a second schematic flowchart of a driving method of a memory device according to an example of the present disclosure.

FIG. 19 is a third schematic flowchart of a driving method of a memory device according to an example of the present disclosure.

FIG. 20 is a fourth schematic flowchart of a driving method of a memory device according to an example of the present disclosure.

FIG. 21 is a fifth schematic flowchart of a driving method of a memory device according to an example of the present disclosure.

FIG. 22 is a sixth schematic flowchart of a driving method of a memory device according to an example of the present disclosure.

FIG. 23 is a seventh schematic flowchart of a driving method of a memory device according to an example of the present disclosure.

### DETAILED DESCRIPTION

The technical solutions of the present disclosure are further described in detail below with reference to the accompanying drawings and detailed description.

In the implementations of the present disclosure, the terms, such as “first”, “second”, and the like, are used for distinguishing similar objects, and are not used for describing a specific order or sequence.

In the implementations of the present disclosure, the terms “A is in contact with B” include a case where A and B are in direct contact, or a case where other components are interposed between A and B, and A is indirectly in contact with B.

It should be understood that “some implementations” or “some examples” mentioned throughout the specification means that specific features, structures, or characteristics related to the implementations are included in at least one implementation of the present disclosure. Thus, “in some implementations” or “in some examples” appearing throughout the specification need not necessarily refer to the same implementation. Further, these particular features, structures, or characteristics may be incorporated in one or more implementations in any suitable manner. It should be understood that, in various implementations of the present disclosure, the sequence numbers of the foregoing processes do not mean a sequence of execution sequences. An execution sequence of each process should be determined by the function and the intrinsic logic thereof. The sequence numbers of the foregoing processes should not constitute any limitation on an implementation process of the implementations of the present disclosure. The foregoing sequence numbers of the implementations of the present disclosure are merely for description, and do not represent the advantages and disadvantages of the implementations.

It should be noted that, in this specification, the terms “including”, “comprising”, or any other variant thereof are intended to cover a non-exclusive inclusion, such that a process, method, article, or device that comprises a series of elements comprises not only those elements but also other elements not explicitly listed, or elements inherent to such processes, methods, articles, or devices. Without further restriction, the elements defined by the statement “include one” do not preclude the presence of additional identical elements in the process, method, article, or device that includes the element.

It is to be understood that the meaning of “on”, “over”, and “above” in the present disclosure should be interpreted in a broadest manner such that “on” not only indicates its “on” something and there is no intervening feature or layer therebetween (e.g., directly on something), but also comprises the meaning of “on” something and intervening features or layers therebetween.

It should be noted that although the present specification is described in terms of implementations, not every implementation comprises only one independent technical solution, and this description of the specification is merely for the sake of clarity, and those skilled in the art should use the specification as a whole, and the technical solutions in the implementations may also be combined appropriately to form other implementations that can be understood by those skilled in the art.

In some example memory devices, such as a dynamic random access memory device (DRAM), a redundant row circuit may be added to the memory cell array of the DRAM, and a standby decoder may be added in the peripheral circuit; wherein the redundant row circuit is connected to the standby decoder through a programmable connector. When it is detected that there is a defect in a certain row of the memory cell array of the DRAM, the standard decoder of the row can be disconnected through a programmable connector (for example, One-Time Programmable, OTP), and the standby row circuit and the standby decoder can be enabled to replace the defective row to cover up the row defect in the manufacturing process and improve the yield and reliability of the DRAM.

Further, the row may be looked up by a content-addressable memory (CAM). CAM is a special memory structure that allows the address to be directly accessed through data content rather than through a traditional address index. In an example, in a row CAM, each storage location contains a data item and a tag associated therewith. The data item is an actually stored data, and the tag is configured to quickly identify and retrieve the data item.

For example, the memory cell array in the memory device may be divided into a plurality of memory banks, which may be operated in parallel. One memory bank corresponds to one row CAM.

During power-on reset of the memory device, the memory controller writes data within the OTP into the row CAM corresponding to each memory bank.

By comparing the input row address to the data stored in the latch, it is determined whether the comparison result matches. If the result does not match, the corresponding row is directly accessed through the CAM. If the result matches, the input row address is determined as a bad row address, and the redundant row address corresponding to the bad row address is matched. The redundant row address may be directly accessed.

It may be understood that the row CAM is coupled to the row decoder in the memory device, and the row decoder may activate the corresponding word line according to the address provided by the row CAM to directly access the address according to the data.

However, in the case that the circuit structure of the row CAM and the OTP is adopted in some examples, since the plurality of CAMs are respectively disposed near the memory bank to which the plurality of CAMs are coupled, for example, one memory bank and the CAM coupled thereto are located in one physical region, the plurality of groups of memory banks and the physical regions where the CAMs are located are sequentially arranged; and the OTP is located on a side of a whole area composed of the plurality of physical regions. In this way, based on the arrangement of different physical regions (bank and CAM), the OTP needs to be connected to the plurality of CAMs using longer lines, respectively. The lengths of the transmission paths between different CAMs and the OTP are different, which is easy to lead to large differences in the time when the CAMs store data, resulting in the delay problem. Moreover, the layout design of the line between the CAM and the OTP is limited by their position relationship, and the complexity is high, which is not conducive to their flexible adjustment in different scenarios.

To resolve at least one of the foregoing problems, implementations of the present disclosure provide a memory device, a driving method thereof, and a memory system, which are beneficial to the flexible adjustment of the layout of lines connecting a memory circuit to the memory banks, and reducing the process cost and product size.

For example, the memory device may include, but is not limited to, one or more of a NAND flash memory (for example, a vertical NAND flash memory), a NOR flash memory, a dynamic random access memory (DRAM), a ferroelectric random access memory (FRAM), a magnetic random access memory (MRAM), a phase change random access memory (PCRAM), a resistive random access memory (RRAM), and a nanometer random access memory (NRAM). Subsequent examples of the present disclosure do not limit the internal structure of the memory device.

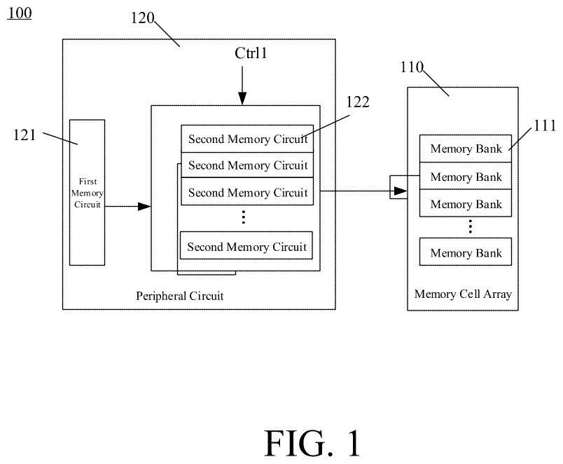

In some implementations, as shown in FIG. 1, the memory device 100 comprises a memory cell array 110 and a peripheral circuit 120.

The memory cell array 110 comprises a plurality of memory banks 111. For example, the memory cell array 110 comprises a plurality of memory cells which may be divided into a plurality of memory banks 111. For example, one memory bank 111 may correspond to a separate row address space and a column address space. Each memory bank 111 may perform read and write operations independently, and the plurality of memory banks 111 may be operated in parallel, thereby improving access efficiency.

A peripheral circuit 120 is coupled to the plurality of memory banks 111. For example, the peripheral circuit 120 may be coupled to the plurality of memory banks 111 through the lines such as bit lines (BL), word lines (WLs), etc., to apply at least one of voltage signals or current signals to the memory cells in each of the memory banks 111, and sense at least one of the voltage signals or the current signals from the memory cells in each of the memory banks 111, to implement logical operations (e.g., program, read, or write operations) of memory cells in the plurality of memory banks 111.

With continued reference to FIG. 1, the above peripheral circuit 120 comprises a first memory circuit 121 and a plurality of second memory circuits 122.

The first memory circuit 121 is configured to store address information of a damaged word line WL_d of the word lines WL coupled with the plurality of memory banks 111. For example, the first memory circuit 121 may include a one-time programmable memory cell (e.g., an OTP cell).

The plurality of second memory circuits 122 are all coupled to the first memory circuit 121 and are configured to be coupled to the redundant word line RWL corresponding to the damaged word line WL_d in response to the first control signal Ctrl1. For example, the second memory circuit 122 may include a content addressable memory cell (e.g., a CAM cell). It is understood that the word line WL comprises a damaged word line WL_d.

Data transmission paths between the plurality of second memory circuits 122 and the first memory circuit 121 are all shorter than data transmission paths between the plurality of second memory circuits 122 and the plurality of memory banks 111. For example, one second memory circuit 122 is coupled to one memory bank 111 through a word line WL. The data transmission path between one second memory circuit 122 and the first memory circuit 121 is shorter than the data transmission path between the second memory circuit 122 and the memory bank 111. The number of the plurality of second memory circuits 122 is not limited by examples provided by the present disclosure, and may be adjusted according to the number of the memory banks 111 in the actual memory device 100.

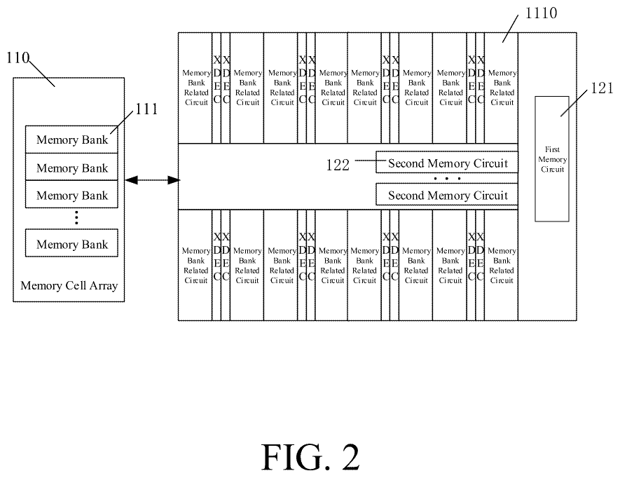

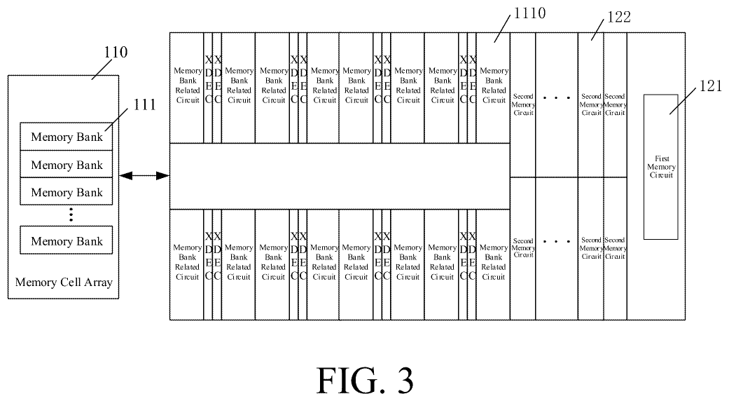

For example, FIGS. 2-3 show the first memory circuit 121, the second memory circuit 122, and the position relationship with the circuit layout of the memory bank related circuits 1110, and the connection relationship with a plurality of memory banks 111 in a memory cell array 110, wherein one of the memory bank related circuits 1110 is coupled to one of the memory banks 111. For example, the memory cell array 110 is disposed in one semiconductor structure, the peripheral circuit 120 is disposed in another semiconductor structure, and the two semiconductor structures may be stacked. In the semiconductor structure in which the peripheral circuit 120 is located, the plurality of second memory circuits 122 may be centrally disposed in an empty space close to the first memory circuit 121 (as shown in FIG. 2) instead of being dispersedly disposed in a vicinity of each of the memory bank related circuits 1110. Alternatively, the plurality of second memory circuits 122 may be centrally disposed on a side of the memory bank related circuit 1110 close to the first memory circuit 121 and located around the first memory circuit 121. For example, as shown in FIG. 3, all the second memory circuits 122 may be disposed between all the memory bank related circuits 1110 and the first memory circuit 121, which can reduce a line length between the plurality of second memory circuits 122 and the first memory circuit 121.

It can be understood that, since the bit field of the row address is large, the time required for the data transmission from the first memory circuit 121 to the second memory circuits 122 is long. Especially when the transmission paths between the first memory circuit 121 and the second memory circuits 122 are long or the difference between the transmission paths between the first memory circuit 121 and different second memory circuits 122 is large, the delay problem is easily generated.

In the above memory device 100, the second memory circuits 122 can disconnect the connection with the damaged word line WL_d in response to the first control signal Ctrl1, and then connect with the redundant word line RWL corresponding to the damaged word line WL_d, and can transmit the data in the second memory circuits 122 to the memory bank 111 via the redundant word line RWL. Considering that the amount of data transmitted between the first memory circuit 121 and the second memory circuits 122 is large, the positional layout relationship of the plurality of second memory circuits 122 and the first memory circuit 121 in the memory device 100 is adjusted, and the data transmission paths between the plurality of second memory circuits 122 and the first memory circuit 121 are all set to be shorter than the data transmission paths between the plurality of second memory circuits 122 and the plurality of memory banks 111. As such, not only the delay of transmitting data from the first memory circuit 121 to the second memory circuits 122 may be reduced, but also the flexible adjustment of the layout of lines between the second memory circuits 122 and the memory banks 111 are facilitated, which is beneficial to reducing the process cost and the product size of the memory device 100.

In addition, as shown in FIGS. 2-3, the memory banks 111 and the second memory circuits 122 are coupled through a row decoder (XDEC), and the address signal is decoded and converted into a row selection signal, so as to control activation and access of a specific row in the memory banks. The structure and the position of the row decoder are not limited in the examples provided in the present disclosure. Considering that the row decoder only needs to decode the determined row address, and that the amount of decoding data is not large and the degree of influence on the data transmission delay is relatively small, the row decoder may be disposed near the memory bank 111 to which the row decoder is coupled.

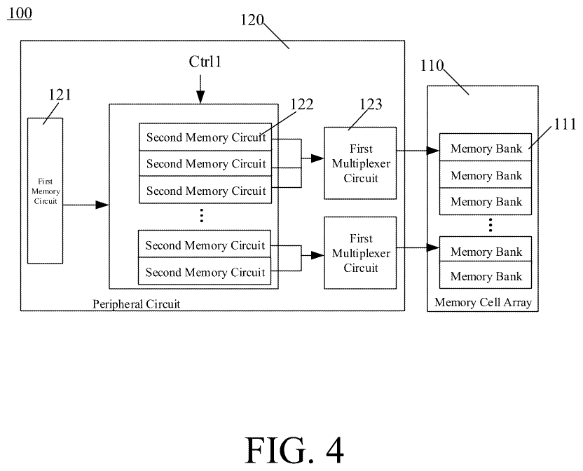

In some examples, as shown in FIG. 4, the peripheral circuit 120 further comprises a first multiplexer circuit 123. For example, the first multiplexer circuit 123 may include a multiplexer (e.g., MUX).

A plurality of inputs of the first multiplexer circuit 123 are respectively coupled to the plurality of second memory circuits 122, and an output of the first multiplexer circuit 123 is coupled to the memory bank 111. For example, the inputs of the first multiplexer circuit 123 may include at least two inputs, the number of the inputs is related to its circuit logic, and may be set according to actual requirements.

In an example, the peripheral circuit 120 may include one or more first multiplexer circuits 123. In a case where the peripheral circuit 120 comprises one first multiplexer circuit 123, the number of the inputs of the first multiplexer circuit 123 may be the same as the number of the second memory circuits 122.

Alternatively, in a case where the peripheral circuit 120 comprises a plurality of first multiplexer circuits 123, the inputs of one first multiplexer circuit 123 comprise at least two first multiplexer circuits 123, and one first multiplexer circuit 123 may be coupled to two second memory circuits 122. Moreover, the number of the second memory circuits 122 coupled to different first multiplexer circuits 123 may be different. For example, a plurality of inputs of some of the first multiplexer circuits 123 may be coupled to three second memory circuits 122. The plurality of inputs of some of the first multiplexer circuits 123 may be coupled to two second memory circuits 122. The number of the first multiplexer circuits 123 and the number of the second memory circuits 122 to which each first multiplexer circuit 123 is coupled is not limited in the present disclosure, and may be adjusted according to actual requirements.

Moreover, the output of the first multiplexer circuit 123 is coupled to the memory bank 111, and the different second memory circuits 122 selectively being connected to one memory bank 111 can be realized. For example, the outputs of the at least two first multiplexer circuits 123 coupled to the different second memory circuits 122 may be coupled to the same memory bank 111. Alternatively, the memory banks 111 coupled to the outputs of the different first multiplexer circuits 123 are different. This is not limited in the examples provided in the present disclosure, and may be adjusted according to actual requirements.

The above first multiplexer circuit 123 is configured to couple the redundant word line RWL corresponding to the damaged word line WL_d with the target memory bank 111 in response to the second control signal Ctrl2, to transmit the data in the second memory circuits 122 to the target memory bank 111.

The memory bank 111 coupled to the damaged word line WL_d may be the same as or different from the target memory bank 111 coupled to the redundant word line RWL corresponding to the damaged word line WL_d.

For example, the memory bank 111 coupled to the damaged word line WL_d is the same as the target memory bank 111 coupled to the redundant word line RWL corresponding to the damaged word line Wl_d. As such, the target memory bank 111 may be quickly selected for storing data, and the corresponding circuit structure is simple.

As another example, the memory bank 111 coupled to the damaged word line WL_d is different from the target memory bank 111 coupled to the redundant word line RWL corresponding to the damaged word line Wl_d. As such, different memory banks 111 may be selected for storing data according to the requirements (for example, information carried by the first control signal Ctrl1), so that the number of times of use of the memory bank 111 with a large number of erasing times can be reduced, and the service life of the memory device 100 can be improved.

In this way, the first multiplexer circuit 123 connects the redundant word line RWL with the target memory bank 111 in response to the second control signal Ctrl2, and transmits the data in the second memory circuits 122 to the target memory bank 111.

In some examples, the peripheral circuit 120 may include a plurality of first multiplexer circuits 123, and the different first multiplexer circuits 123 may be operated in parallel in response to the second control signal Ctrl2, respectively. The different first multiplexer circuits 123 may be connected to the different target memory banks 111 in response to the second control signal Ctrl2.

And the memory bank 111 coupled to the damaged word line WL_d may be the same as or different from the target memory bank 111 coupled to the redundant word line RWL corresponding to the damaged word line WL_d. For the effect of this example, reference may be made to the description of the functional effect of the one first multiplexer circuit 123 in the foregoing example, and details are not described herein again.

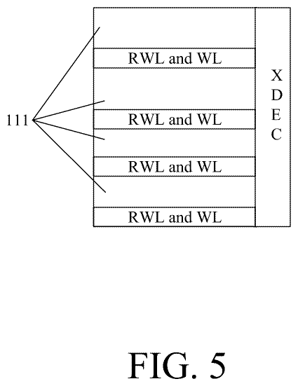

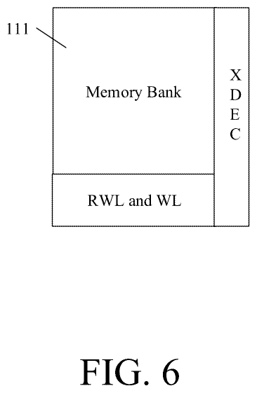

In some examples, in a position relationship of the layout of lines of one memory bank 111 and a redundant word line RWL (and row decoder) coupled thereto as shown in FIGS. 5-6, the one memory bank 111 may divide a plurality of memory cells into a plurality of sub-sections, each of which is disposed adjacent to a corresponding redundant word line RWL (as shown in FIG. 5). In this way, the transmission path lengths between the second memory circuits 122 and the redundant word line RWL can be reduced.

Alternatively, a plurality of memory cells of one memory bank 111 are centrally disposed in one region, and the redundant word lines RWL are centrally disposed in one region, and are coupled to (a row decoder or) the second memory circuits 122 via different leads (as shown in FIG. 6).

The connection relationship between each memory bank 111 (for example, the memory cell) and each word line WL or redundant word line RWL is not limited in the present disclosure, and may be set according to actual requirements.

For example, as shown in FIG. 6, the word line WL is coupled to the second memory circuit 122. The redundant word line RWL is coupled to the memory bank 111 and the second memory circuit 122. One redundant word line RWL corresponds to one word line WL.

A plurality of redundant word lines RWL are sequentially adjacent to each other, and the plurality of redundant word lines RWL coupled to one memory bank 111 are disposed on the same side of the memory bank 111.

In this way, the route design between the memory banks 111, the redundant word lines RWL and the second memory circuits 122 is simplified, and the flexibility of the line design is improved. Moreover, based on the layout position relationship between the second memory circuits 122 and the memory banks 111 as shown in FIGS. 2-3, designing the layout position relationship of one memory bank 111 and the redundant word line RWL coupled to the memory bank 111 as shown in FIG. 6 is also beneficial to reducing the transmission path length between the second memory circuit and the redundant word line.

In some examples, the plurality of second memory circuits 122 are configured to couple to the at least one redundant word line RWL or the at least one word line WL in response to the plurality of first control signals Ctrl1, respectively.

As an example, the memory cell array 110 comprises a plurality of memory banks 111. One memory bank 111 may correspond to a separate row address space and a column address space (as shown in FIGS. 5-6). One second memory circuit is configured to connect one memory bank 111 with one second memory circuit 122 in response to one first control signal Ctrl1 being coupled to at least one redundant word line RWL or at least one word line WL.

That is, different first control signals Ctrl1 may indicate that different second memory circuits 122 are in connection with corresponding memory banks 111.

In the case where a damaged word line WL_d is detected, a memory bank 111 may be connected with a second memory circuit 122 through the redundant word line RWL, or the memory bank 111 may be connected with the second memory circuit 122 through a word line WL other than the damaged word line WL_d. In this way, each memory bank 111 may independently perform read/write operations. In a case where read/write operations are performed on different memory banks, a plurality of second memory circuits 122 may be operated in parallel in response to a plurality of first control signals Ctrl1, respectively, so as to improve access efficiency.

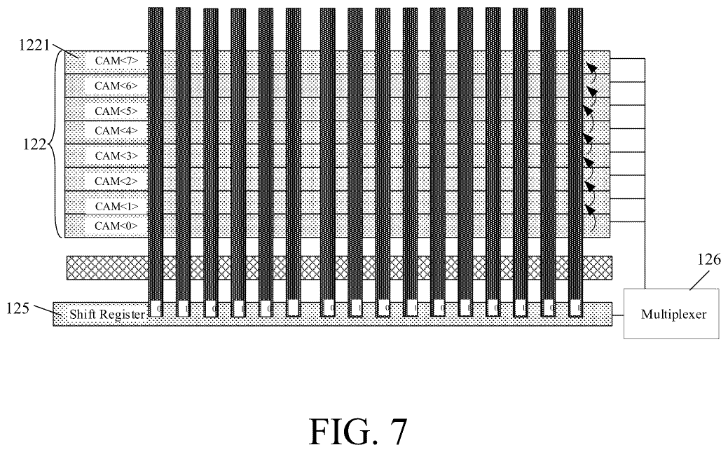

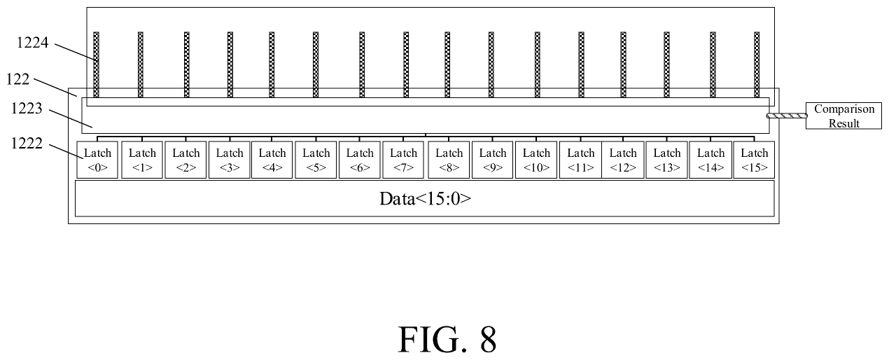

In some examples, as shown in FIGS. 7-8, a second memory circuit 122 comprises a content addressable memory cell 1221.

For example, the second memory circuit 122 comprises a content addressable memory. The content addressable memory cell 1221 comprises a CAM<n>. For example, as shown in FIG. 7, the second memory circuit 122 comprises CAM<0>, CAM<1>, CAM<2>, . . . and CAM<7>.

With continued reference to FIG. 7, the peripheral circuit 120 further comprises a shift register 125 and a multiplexer 126. For example, during a power-on (POR) process of the memory device 100, a second memory circuit 122 may acquire information of the damaged word line WL_d stored in a first memory circuit 121. For example, the multiplexer 126 may sequentially select content addressable memory cells CAM<0>, CAM<1>, CAM<2>, . . . and CAM<7>. When one content addressable memory cell 1221 is selected, information of the corresponding damaged word line WL_d may be transferred from the first memory circuit 121 to the shift register 125, and then written to the selected content addressable memory cell 1221 from the shift register 125.

Next, another content addressable memory cell 1221 may be selected, the shift register 125 may be reset, and the above operations may be repeated until the second memory circuit 122 acquires information of all the damaged word lines WL_d. As such, the information of the damaged word lines WL_d stored in the first memory circuit 121 may be sequentially transferred into the plurality of content addressable memory cells 1221.

There is no long data transmission line between the multiplexer 126 and the shift register 125. They may be a structure integrated together, which is not limited in the examples provided in the present disclosure.

In some examples, as shown in FIG. 8, the content addressable memory cell 1221 comprises a second memory element 1222 and a comparison circuit 1223.

The second memory element 1222 is configured to store identification information and address information of the damaged word line WL_d acquired from the first memory circuit 121, and identification information of the redundant word line RWL corresponding to the damaged word line WL_d, and address information of the redundant word line RWL. For example, the second memory element 1222 may include a plurality of second memory elements 1222, and the second memory element 1222 may include a latch. For example, as shown in FIG. 8, the content addressable memory cell 1221 comprises 16 latches Latch<0>, Latch<1>, Latch<2>, . . . and Latch<15>.

The comparison circuit 1223 is configured to compare the user data with the address information of the damaged word line WL_d stored in the second memory element 1222. When the user data is the same as the address information of the damaged word line WL_d, the redundant word line RWL corresponding to the damaged word line WL_d is coupled.

For example, the comparison circuit 1223 is coupled between the data paths 1224 (as shown in FIG. 8) and the content addressable memory cell 1221, and is configured to compare the user data with the address information of the damaged word line WL_d stored in the second memory element 1222, and output a comparison result. For example, the comparison circuit 1223 may include a plurality of comparators. One comparator may compare data carried by one data path 1224 (shown in FIG. 8) with data in a corresponding latch. When the bit value stored in each latch is equal to the bit value carried by the corresponding data line of the data path, the comparison result may be a logic value of “1” (e.g., a higher voltage), which may be characterized as the user data being the same as the address information of the damaged word line WL_d, and the redundant word line RWL corresponding to the damaged word line WL_d is coupled.

As such, the content addressable memory cell 1221 enables connection of the second memory circuit 122 with the redundant word line RWL through the second memory element 1222 and the comparison circuit 1223.

Additionally, the comparison circuit 1223 may also be external to the content addressable memory cell 1221. For example, the comparison circuit 1223 may be coupled between the data path and the content addressable memory cell 1221 (e.g., the second memory element 1222 of the content addressable memory cell 1221). As such, in the power-on POR process, the peripheral circuit may be configured to write data from the data path to the content addressable memory cell 1221. That is, the data path may be connected to the content addressable memory cell 1221, may bypass the comparison circuit 1223, or ignore the comparison result.

A number of the content addressable memory cells 1221 in the above second memory circuit 122, a number of the data paths 1224, and a number of corresponding latches may be set according to actual conditions. For example, the content addressable memory cell 1221 shown in FIG. 7 comprises 8 CAMs. As shown in FIG. 8, the data path 1224 comprises 16 data lines (the corresponding latches include 16 latches). The examples provided in the present disclosure are not limited.

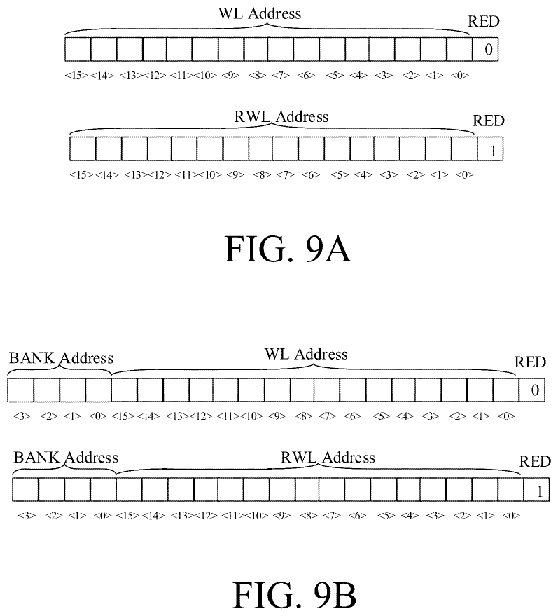

In some examples, as shown in FIG. 9A, the above second memory element 1222 stores address information of the damaged word line WL_d and identification information RED (e.g., “0”) of the damaged word line WL_d, and address information and identification information RED (e.g., “1”) of the redundant word line RWL corresponding to the damaged word line WL_d.

Alternatively, as shown in FIG. 9B, the second memory element 1222 stores address information of the damaged word line WL_d, identification information RED (e.g., “0”) of the damaged word line WL_d, address information of the memory bank 111 coupled to the damaged word line WL_d, address information and identification information RED (e.g., “1”) of the redundant word line RWL corresponding to the damaged word line WL_d, and address information of the memory bank 111 coupled to the redundant word line RWL.

The address information of the memory bank 111 coupled to the damaged word line WL_d may be the same as or different from the address information of the memory bank 111 coupled to the redundant word line RWL.

For example, the address information of the memory bank 111 coupled to the damaged word line WL_d is the same as the address information of the memory bank 111 coupled to the redundant word line RWL. As such, the target memory bank 111 may be quickly selected to store data, and the corresponding circuit structure is simple.

Alternatively, the address information of the memory bank 111 coupled to the damaged word line WL_d may be different from the address information of the memory bank 111 coupled to the redundant word line RWL. Different memory banks 111 may be selected for storing data according to requirements (for example, information carried by the first control signal Ctrl1), so that the number of times of use of the memory bank 111 with a large number of erasing times can be reduced, and the service life of the memory device can be improved.

For example, the address information of the memory bank 111 may contain data consisting of 4 bits (1 square in the figure represent 1 bit of data), and the address information of the memory bank 111 is not limited in the example provided by the present disclosure.

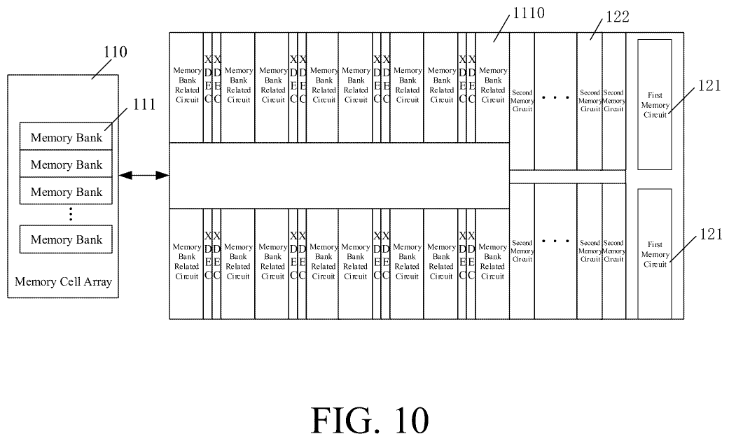

In some examples, the peripheral circuit 120 may include a plurality of first memory circuits 121. For example, FIG. 10 shows that, in the peripheral circuit 120, the first memory circuit 121, the second memory circuit 122, and the position relationship with the circuit layout of the memory bank related circuit 1110 and the connection relationship with a plurality of memory banks 111 in a memory cell array 110, wherein one memory bank related circuit 1110 is coupled to one memory bank 111. The peripheral circuit 120 may include two first memory circuits 121. One first memory circuit 121 may be coupled to a part of the second memory circuits 122, and another first memory circuit 121 may be coupled to another part of the second memory circuits 122. Alternatively, one first memory circuit 121 may be coupled to all second memory circuits 122, and another first memory circuit 121 may be coupled to all second memory circuits 122.

The number of the first memory circuits 121 and the number of the second memory circuits 122 coupled to one first memory circuit 121 in the examples provided by the present disclosure are not limited, and may be set according to actual requirements.

In some examples, the first memory circuit 121 may include a one-time programmable memory. For example, the first memory circuit 121 may be an anti-fuse OTP memory.

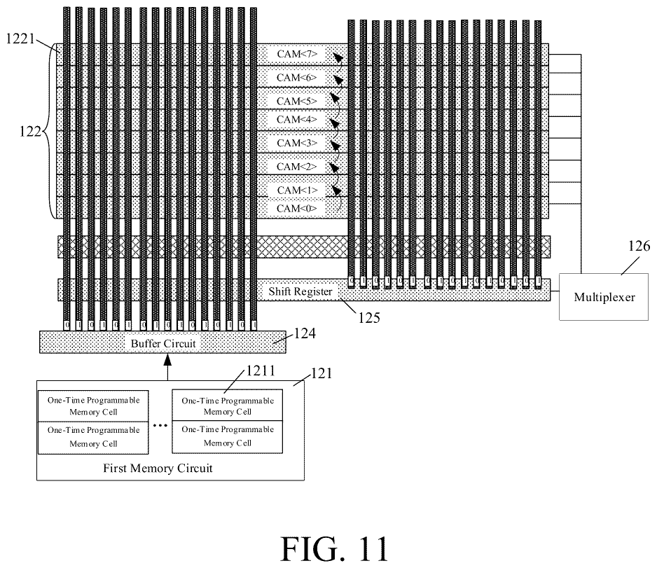

As shown in FIG. 11, the first memory circuit 121 comprises a one-time programmable memory cell 1211 (e.g., an OTP cell). For example, the first memory circuit 121 may include a plurality of OTP memory cells.

It is to be understood that one-time programmable memory (OTP) is a special non-volatile memory, which is characterized by only allowing programming once, and cannot be changed or deleted once data is written. The OTP memory may be configured to store fixed configuration information, a unique device identifier, an encryption key, an identity verification token seed, and the like, and these contents are not modified within the life cycle of the device. The OTP memory has high security since it cannot be erased or rewritten again, preventing malicious or unauthorized data tampering.

The one-time programmable memory cell 1211 comprises a first memory element and at least one transistor (not shown in the figure). For example, the first memory element may include a register. The first memory element stores address information of the damaged word line WL_d.

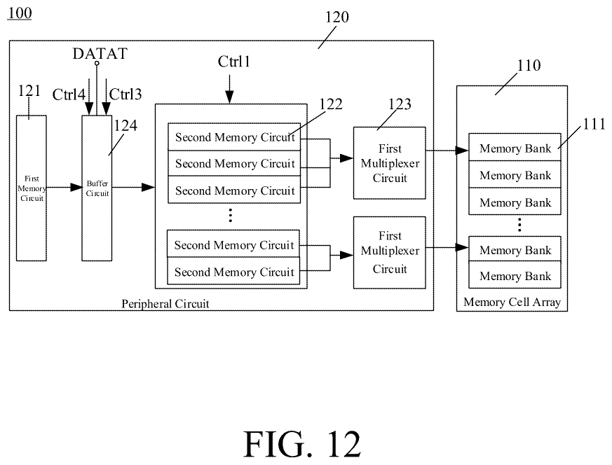

In some examples, as shown in FIGS. 11-12, the peripheral circuit 120 further comprises a buffer circuit 124.

The buffer circuit 124 is coupled to the plurality of second memory circuits 122, the first memory circuit 121 and the data transmission interface, and is configured to transmit the user data transmitted by the data transmission interface to the second memory circuit 122 in response to a third control signal Ctrl3.

In this way, the buffer circuit 124 temporarily stores the user data, transmits the user data to the second memory circuit 122 in response to the third control signal Ctrl3, and compares the user data with the information of the damaged word line WL_d subsequently.

And, the buffer circuit 124 is further configured to transfer the data in the first memory circuit 121 to the plurality of second memory circuits 122 in response to a fourth control signal Ctrl4.

In this way, considering that the amount of field information of the damaged word line WL_d is large, the buffer circuit 124 temporarily stores the field information of the damaged word line WL_d, and plays a role of caching in the process of transferring the data in the first memory circuit 121 to the plurality of second memory circuits 122 in response to the fourth control signal Ctrl4, thereby improving the performance of data transmission between the first memory circuit 121 and the plurality of second memory circuits 122.

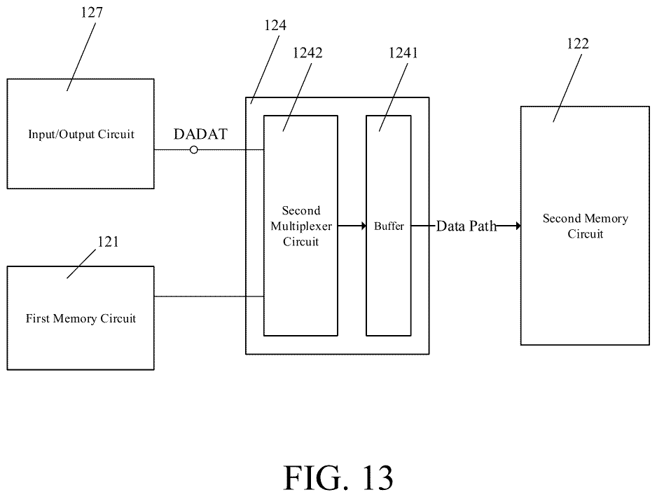

In some examples, as shown in FIG. 13, the above buffer circuit 124 comprises a buffer 1241 and a second multiplexer circuit 1242 coupled to the buffer 1241.

For example, the second multiplexer circuit 1242 may have at least two inputs. For example, the second multiplexer circuit 1242 comprises a first input and a second input, and an output (not shown in the figure). A first input of the second multiplexer circuit 1242 is coupled to the data transmission interface DADAT, a second input of the second multiplexer circuit 1242 is coupled to the first memory circuit 121, and an output of the second multiplexer circuit 1242 is coupled to the buffer 1241.

And, the buffer 1241 is coupled to the plurality of second memory circuits 122 through a data path (e.g., a data line).

In some examples, as shown in FIG. 13, the peripheral circuit 120 further comprises an input/output circuit 127. The input/output circuit 127 is coupled to the data transmission interface DADAT, and is configured to receive user data and output the user data to the data transmission interface DADAT.

For example, the input/output circuit 127 may include a circuit structure (for example, an input/output circuit (I/O circuit)) for implementing signal transmission and interaction between the memory device 100 and an external device. For example, the input/output circuit 127 may include a buffer, a level shifter, and an overvoltage and overcurrent protection circuit, which are not limited in the examples provided in the present disclosure, and mainly implement a function of receiving user data and outputting the user data to the data transmission interface DADAT.

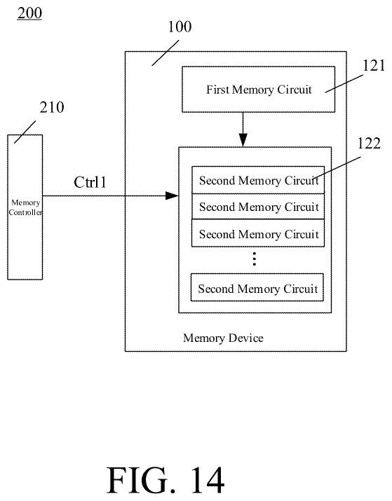

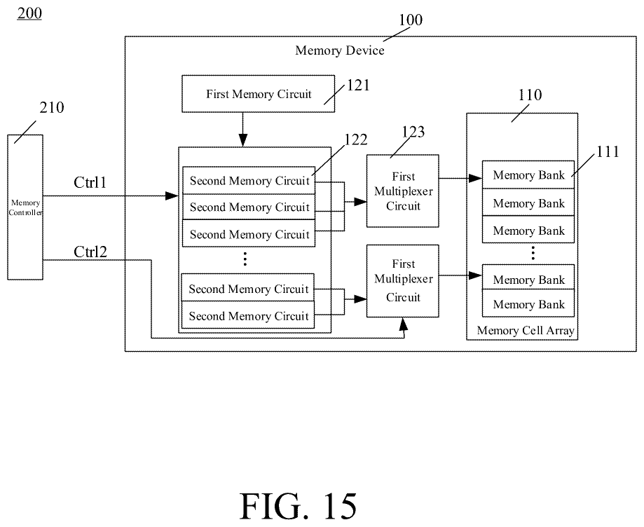

As shown in FIGS. 14-15, an implementation of the present disclosure provides a memory system 200. The memory system 200 comprises a memory device 100 and a memory controller 210.

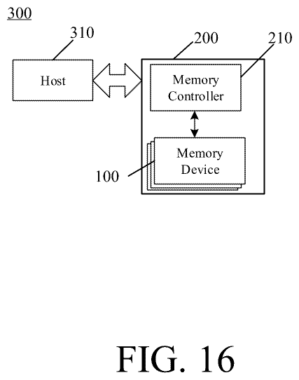

For example, the memory controller 210 may manage data in the memory device 100 and communicate with the host 310 (shown in FIG. 16). The memory controller 210 may be configured to control operations such as reading, erasing, and programming of the memory device 100; may also be configured to manage various functions regarding data stored in or to be stored in the memory device 100, comprising, but not limited to, bad block management, garbage collection, logical-to-physical address translation, wear leveling, etc.; and may also be configured to process the error checking and correction code (ECC) regarding data read from or written into the memory device 100.

In some examples, as shown in FIG. 14, the memory device 100 comprises a first memory circuit 121 and a second memory circuit 122.

And, the memory controller 210 is coupled to the memory device 100 and is configured to transfer the address information of the damaged word line WL_d stored in the first memory circuit 121 to the second memory circuit 122; and transmit the user data to the second memory circuit 122; and is further configured to output the first control signal Ctrl1 to instruct the second memory circuit 122 to couple to a redundant word line RWL corresponding to the damaged word line WL_d when the user data is the same as the address information of the damaged word line WL_d after comparison.

For example, during a power-on (POR) process of the memory device 100, a second memory circuit 122 may acquire information of the damaged word line WL_d stored in a first memory circuit 121. When the first memory circuit 121 is coupled to the second memory circuit 122 through the buffer circuit 124, the buffer circuit 124 buffers the information of the damaged word line WL_d stored in the first memory circuit 121, and transfers the information of the damaged word line WL_d to the plurality of second memory circuits 122 in response to the fourth control signal. It may be understood that the power-on reset signal may be output by the memory controller 210, or may be output by the host 310 (as shown in FIG. 16), which is not limited in the examples provided in the present disclosure.

The buffer circuit 124 temporarily stores the user data, and transmits the user data to the second memory circuit 122 in response to a third control signal Ctrl3.

Then, the memory controller 210 outputs the first control signal Ctrl1, and the second memory circuit 122 is coupled to the redundant word line RWL corresponding to the damaged word line WL_d when the user data is the same as the address information of the damaged word line WL_d after comparison.

In some examples, as shown in FIG. 15, the memory device 100 further comprises a first multiplexer circuit 123.

The memory controller 210 is further configured to output a second control signal Ctrl2 to instruct the first multiplexer circuit 123 to transmit data within the second memory circuit 122 to the target memory bank 111 coupled to the redundant word line RWL. The memory bank 111 coupled to the damaged word line WL_d may be the same as or different from the target memory bank 111 coupled to the redundant word line RWL corresponding to the damaged word line WL_d.

For example, the memory bank 111 coupled to the damaged word line WL_d is the same as the target memory bank 111 coupled to the redundant word line RWL corresponding to the damaged word line Wl_d. As such, the target memory bank 111 may be quickly selected for storing data, and the corresponding circuit structure is simple.

As another example, the memory bank 111 coupled to the damaged word line WL_d is different from the target memory bank 111 coupled to the redundant word line RWL corresponding to the damaged word line WL_d. The data in the second memory circuit 122 may be transmitted to the different target memory banks 111 through the information carried by the different second control signals Ctrl2. For example, the target memory bank 111 may be selected according to factors such as the number of erased times of the memory bank 111, so that the number of times of use of the memory bank 111 with a large number of erasing times can be reduced, and the service life of the memory device 100 can be improved.

In this way, the first multiplexer circuit 123 connects the redundant word line RWL with the target memory bank 111 in response to the second control signal Ctrl2, and transmits the data in the second memory circuits 122 to the target memory bank 111.

As shown in FIG. 16, the implementation of the present disclosure illustrates an electronic system 300. For example, the electronic system 300 may include, but are not limited to, a mobile phone, a desktop computer, a laptop computer, a tablet computer, a vehicle computer, a game console, a printer, a pointing device, a wearable electronic device, a smart sensor, a virtual reality (VR) device, an augmented reality (AR) device, or any other suitable electronic device having the memory device 100 therein.

With continued reference to FIG. 16, the electronic system 300 may include a host 310 and a memory system 200.

The host 310 may be a processor (for example, a central processing unit (CPU), or a system on chip (SoC) (for example, an application processor (AP)) of the electronic device. The host 310 may be configured to send or receive data to or from the memory system 200.

The memory system 200 comprises a memory controller 210 and one or more memory devices 100, as well as other integrated circuit structures for signal transmission. The memory controller 210 and the one or more memory devices 100 may be integrated and packaged in the same storage device. In this way, it is beneficial to applying the memory system 200 to different types of end electronic products.

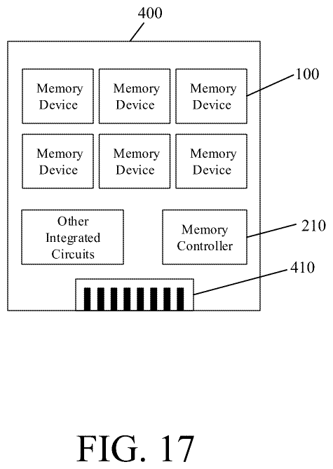

For example, as shown in FIG. 17, the present disclosure provides a readable storage medium 400. The readable storage medium 400 comprises a stored computer program or instruction; and when the computer program or the instruction is executed, the device where the computer readable storage medium is located is controlled to implement the driving method of the memory device 100 provided in any one of the following examples.

For example, the type of the readable storage medium 400 comprises: the type of the storage device integrating the memory controller 210 and the one or more memory devices 100 comprising other types of storage devices such as an universal flash storage (UFS) or an embedded multi-media card (eMMC).

There are a plurality of integrated circuits of the storage device, for example, a memory card formed by integrating a single memory device 100 and a memory controller 210, or solid-state drive (SSD) formed by integrating a plurality of memory devices 100 and a memory controller 210. It will be appreciated that at least one of the storage capacity or operating speed of the SSD is greater than at least one of the storage capacity or operating speed of the memory card.

For example, with continued reference to FIG. 17, the readable storage medium 400 further comprises a connector 410. The connector 410 is configured to couple the readable storage medium 400 with a host (e.g., the host 310 in FIG. 16). For example, the connector 410 comprises a gold finger.

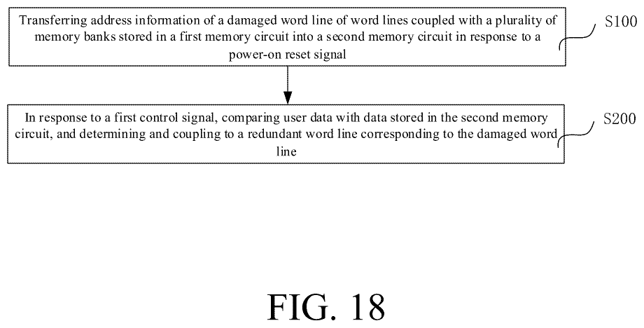

As shown in FIGS. 18-23, the implementation of the present disclosure provides a driving method of a memory device 100, which can instruct, in response to a control signal, a second memory circuit 122 in the memory device 100 to couple to the redundant word line RWL corresponding to the damaged word line WL_d, and write data into the target memory bank 111 through the redundant word line RWL.

In some examples, as shown in FIG. 18, the driving method comprises: S100 and S200.

S100: transferring address information of a damaged word line WL_d of word lines WL coupled with a plurality of memory banks 111 stored in a first memory circuit 121 into a second memory circuit 122 in response to a power-on reset signal POR.

It may be understood that the power-on reset signal may be output by the memory controller 210, or may be output by the host 310 (as shown in FIG. 16), which is not limited in the examples provided in the present disclosure.

For example, the first memory circuit 121 stores address information of the damaged word line WL_d. The first memory circuit 121 transfers the address information of the damaged word line WL_d into the buffer circuit 124 (as shown in FIG. 12) in response to the power-on reset signal POR, and transmits it to the second memory circuit 122 through the buffer circuit 124.

The buffer circuit 124 temporarily stores the user data, and transmits the user data to the second memory circuit 122 in response to a third control signal Ctrl3.

S200: in response to a first control signal Ctrl1, comparing user data with data stored in the second memory circuit 122, and determining and coupling to a redundant word line RWL corresponding to the damaged word line WL_d.

A data transmission path between the second memory circuit 122 and the first memory circuit 121 is shorter than a path from the second memory circuit 122 to the memory bank 111 through the coupled redundant word line RWL.

For example, as shown in FIG. 1, the second memory circuit 122 is coupled to the first memory circuit 121, and when the address information of the damaged word line WL_d is acquired, the second memory circuit 122 compare the user data with the data stored in the second memory circuit 122 in response to the first control signal Ctrl1, determines and couples to the redundant word line RWL corresponding to the damaged word line WL_d, and then writes the data into the target memory bank 111 through the redundant word line RWL.

Considering that the amount of data transmitted between the first memory circuit 121 and the second memory circuits 122 is large, the positional layout relationship of the plurality of second memory circuits 122 and the first memory circuit 121 in the memory device 100 is adjusted, and the data transmission paths between the plurality of second memory circuits 122 and the first memory circuit 121 are all set to be shorter than the data transmission paths between the plurality of second memory circuits 122 and the plurality of memory banks 111. As such, not only the delay of transmitting data from the first memory circuit 121 to the second memory circuits 122 is reduced, but also the flexible adjustment of the layout of lines between the second memory circuits 122 and the memory banks 111 are facilitated, which is beneficial to reducing the process cost and the product size.

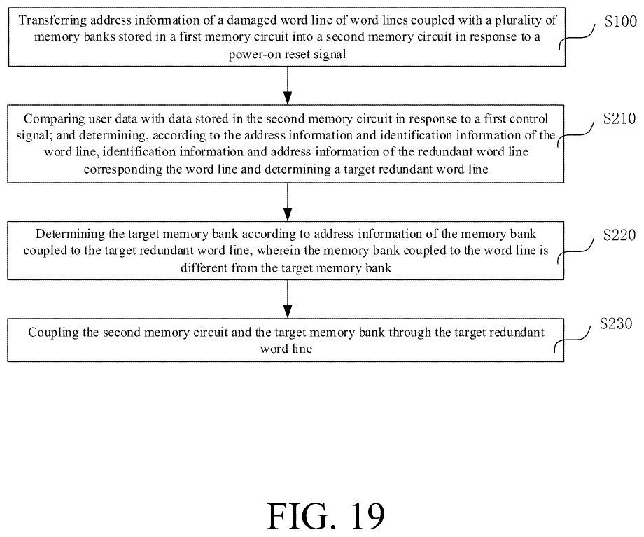

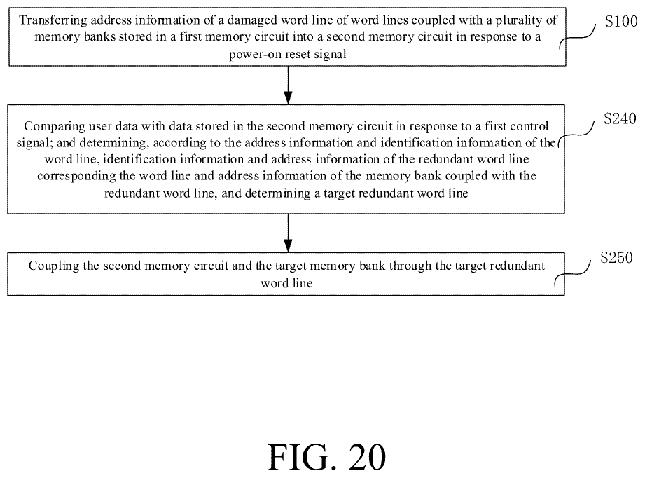

According to different information stored in the first memory circuit 121, for example, the first memory circuit 121 may store address information and identification information of the damaged word line WL_d, and identification information and address information of the redundant word line RWL corresponding to the damaged word line WL_d, and address information of the memory bank 111 coupled to the redundant word line RWL (logic of the operations of the method shown in FIG. 19); alternatively, the first memory circuit 121 may also store the address information and the identification information of the damaged word line WL_d, and the identification information and the address information of the redundant word line RWL corresponding to the damaged word line WL_d (logic of the operations of the method shown in FIG. 20). The following example second memory circuit 122 is based on two different types of control methods.

In some examples, as shown in FIG. 19, in the above operation S200, determining and coupling to the redundant word line RWL corresponding to the damaged word line WL_d comprises S210-S230.

S210: determining, according to the address information and the identification information of the damaged word line WL_d, identification information and address information of the redundant word line RWL corresponding to the damaged word line WL_d, and determining a target redundant word line RWL.

It can be understood that the “target redundant word line RWL” refers to a redundant word line RWL selected during data transmission, and does not represent a unique redundant word line RWL.

For example, as shown in FIG. 8, a second memory circuit 122 comprises a second memory element 1222 and a comparison circuit 1223. The second memory element 1222 is configured to store identification information and address information of the damaged word line WL_d acquired from the first memory circuit 121, and identification information of the redundant word line RWL corresponding to the damaged word line WL_d, and address information of the redundant word line RWL. The comparison circuit 1223 is configured to compare the user data with the address information of the damaged word line WL_d stored in the second memory element 1222. When the user data is the same as the address information of the damaged word line WL_d, the redundant word line RWL corresponding to the damaged word line WL_d is coupled.

S220: determining the target memory bank 111 according to the address information of the memory bank 111 coupled to the target redundant word line RWL, wherein the memory bank 111 coupled to the damaged word line WL_d is different from the target memory bank 111.

It may be understood that the “target memory bank 111” refers to one memory bank 111 selected during the data transmission, and does not represent a unique one memory bank 111.

For example, one redundant word line RWL may correspond to one memory bank 111 with preset, and the redundant word line RWL is connected to its corresponding memory bank 111 in response to the second control signal Ctrl2 through the address information of the memory bank 111.

It may be understood that the memory controller 210 is further configured to output the second control signal Ctrl2, and may carry the information directed to the target memory bank 111 according to the second control signal Ctrl2, and couple the target redundant word line RWL with the target memory bank 111. This target memory bank 111 and the target memory bank 111 coupled with the damaged word line WL_d may be the same memory bank 111, or may be different memory banks 111. For example, the target memory bank 111 may be selected according to factors such as the number of erased times of the memory bank 111, which is beneficial to improving the service life of the memory device 100.

S230: coupling the second memory circuit 122 with the target memory bank 111 through the target redundant word line RWL.

For example, as shown in FIG. 15, after the second memory circuit 122 is coupled to the target redundant word line RWL, the first multiplexer circuit 123 may be utilized to select which memory bank 111 the target redundant word line RWL is coupled to, so as to connect the second memory circuit 122 with the target memory bank 111. The memory bank 111 coupled to the damaged word line WL_d may be the same as or different from the target memory bank 111 coupled to the redundant word line RWL corresponding to the damaged word line WL_d.

It may be understood that the memory controller 210 is further configured to output the second control signal Ctrl2, and may carry the information directed to the target memory bank 111 according to the second control signal Ctrl2, and couple the target redundant word line RWL with the target memory bank 111. This target memory bank 111 and the target memory bank 111 coupled with the damaged word line WL_d may be the same memory bank 111 or may be different memory banks 111.

For example, the memory bank 111 coupled to the damaged word line WL_d is the same as the target memory bank 111 coupled to the redundant word line RWL corresponding to the damaged word line Wl_d. As such, the target memory bank 111 may be quickly selected for storing data, and the corresponding circuit structure is simple.

Alternatively, the memory bank 111 coupled to the damaged word line WL_d is different from the target memory bank 111 coupled to the redundant word line RWL corresponding to the damaged word line Wl_d. Different memory banks 111 may be selected for storing data according to requirements (for example, information carried by the first control signal Ctrl1), so that the number of times of use of the memory bank 111 with a large number of erasing times can be reduced, and the service life of the memory device 100 can be improved.

In some other examples, as shown in FIG. 20, in the above operation S200, determining and coupling to the redundant word line RWL corresponding to the damaged word line WL_d comprises S240 and S250.

S240: according to the address information and the identification information of the damaged word line WL_d, determining identification information and address information of the redundant word line RWL corresponding to the damaged word line WL_d, and the address information of the memory bank 111 coupled to the redundant word line RWL, and determining a target redundant word line RWL.

For example, a second memory circuit 122 comprises a second memory element 1222 and a comparison circuit 1223. The second memory element 1222 is configured to store the identification information and the address information of the damaged word line WL_d acquired from the first memory circuit 121, and store identification information and address information of the redundant word line RWL corresponding to the damaged word line WL_d.

The comparison circuit 1223 is configured to compare the user data with the address information of the damaged word line WL_d stored in the second memory element 1222. When the user data is the same as the address information of the damaged word line WL_d, the redundant word line RWL corresponding to the damaged word line WL_d is coupled.

S250: coupling the second memory circuit 122 and the target memory bank 111 through the target redundant word line RWL.

For example, one redundant word line RWL may correspond to one memory bank 111 with preset, and the redundant word line RWL is connected to its corresponding memory bank 111 in response to the second control signal Ctrl2 through the address information of the memory bank 111.

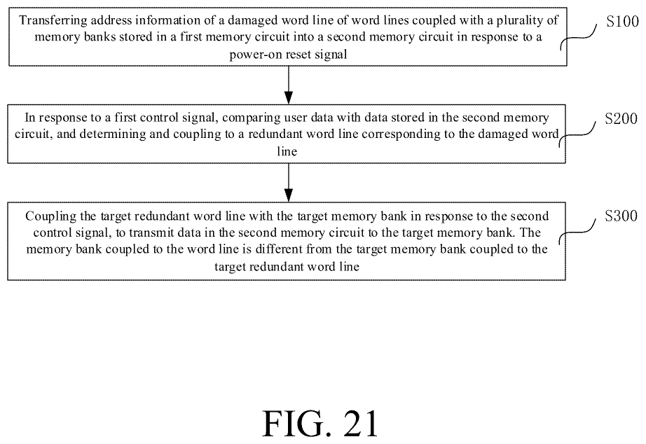

In some examples, as shown in FIG. 21, the method further comprises S300.

S300: coupling the target redundant word line RWL with the target memory bank 111 in response to the second control signal Ctrl2, to transmit data in the second memory circuit 122 to the target memory bank 111. The memory bank 111 coupled to the damaged word line WL_d is different from the target memory bank 111 coupled to the target redundant word line RWL.

For example, the first multiplexer circuit 123 connects the target redundant word line RWL with the target memory bank 111 in response to the second control signal Ctrl2, and the data in the second memory circuit 122 may be transmitted to different target memory banks 111 through the information carried by different second control signals Ctrl2.

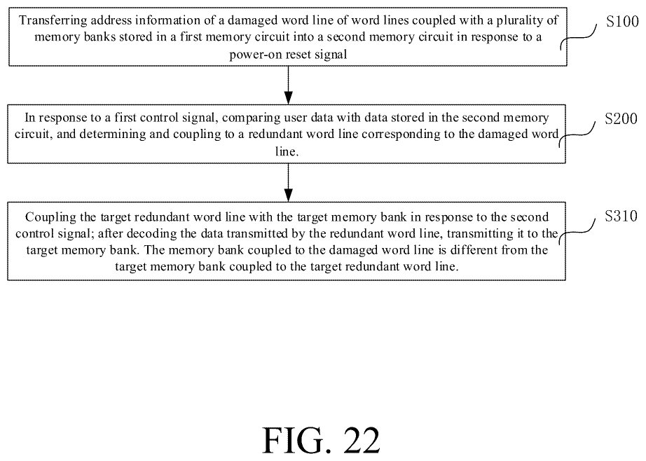

In some examples, as shown in FIG. 22, in the above operation S300, transmitting data in the second memory circuit 122 to the target memory bank 111 comprises S310.

S310: after decoding the data transmitted by the redundant word line RWL, transmitting it to the target memory bank 111.

For example, the second memory circuit 122 is coupled to the memory bank 111 through the row decoder (e.g., XDEC shown in FIGS. 2 and 3). After the row decoder decodes the data transmitted by the redundant word line RWL, it is transmitted to the target memory bank 111.

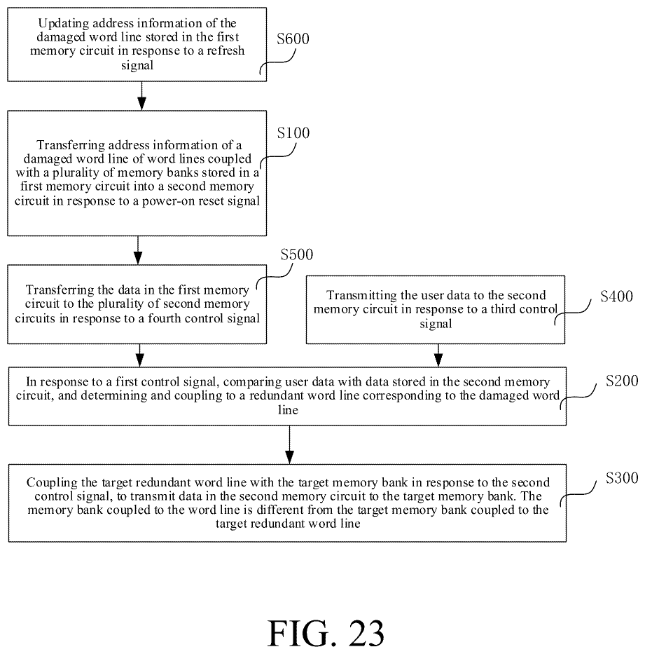

In some examples, as shown in FIG. 23, the method comprises: S400 and S500.

S400: transmitting the user data to the second memory circuit 122 in response to a third control signal Ctrl3.

S500: transferring the data in the first memory circuit 121 to the plurality of second memory circuits 122 in response to a fourth control signal Ctrl4.

For example, as shown in FIG. 12, the buffer circuit 124 temporarily stores the user data, and transmits the user data to the second memory circuit 122 in response to the third control signal Ctrl3 for comparing the user data with the information of the damaged word line WL_d subsequently.

The buffer circuit 124 temporarily stores information in the first memory circuit 121, and transfers the data in the first memory circuit 121 to the plurality of second memory circuits 122 in response to the fourth control signal Ctrl4.

Moreover, considering that the amount of field information of the damaged word line WL_d is large, the buffer circuit 124 plays a role of caching in the process of transferring the data in the first memory circuit 121 to the plurality of second memory circuits 122 in response to the fourth control signal Ctrl4, thereby improving the performance of data transmission between the first memory circuit 121 and the plurality of second memory circuits 122.

In some examples, as shown in FIG. 23, the method further comprises S600.

S600: updating address information of the damaged word line stored in the first memory circuit 121 in response to a refresh signal Ref.

For example, the first memory circuit 121 may include a non-volatile memory (for example, a register), and in a case where an error exists in the information of the damaged word line WL_d determined according to the actual data statistics or the damaged word line WL_d needs to be replaced, the first memory circuit 121 may update the address information of the damaged word line WL_d stored in the first memory circuit 121 in response to the refresh signal Ref. In this way, the application scenario of the first memory circuit 121 can be enlarged.

In view of the above, implementations of the present disclosure provide a memory device, a driving method thereof, and a memory system for solving at least one problem, which can realize flexible adjustment of the layout of lines of a memory circuit connecting a memory bank, and reduce process cost and product size.

The technical solutions of the implementations of the present disclosure are implemented as follows.

According to a first aspect, implementations of the present disclosure provide a memory device. The memory device comprises a memory cell array and a peripheral circuit. The memory cell array comprises a plurality of memory banks. The peripheral circuit is coupled to the plurality of memory banks.

The peripheral circuit comprises a first memory circuit and a plurality of second memory circuits. The first memory circuit is configured to store address information of a damaged word line of word lines coupled with the plurality of memory banks. The plurality of second memory circuits are all coupled with the first memory circuit, and one of the plurality of second memory circuits is configured to couple to a redundant word line corresponding to the damaged word line in response to a first control signal. Data transmission paths between the plurality of second memory circuits and the first memory circuit are all shorter than data transmission paths between the plurality of second memory circuits and the plurality of memory banks.

In some examples, the peripheral circuit further comprises a first multiplexer circuit, wherein a plurality of inputs of the first multiplexer circuit are respectively coupled to the plurality of second memory circuits, and an output of the first multiplexer circuit is coupled to the memory banks.

The first multiplexer circuit is configured to couple the redundant word line corresponding to the damaged word line with a target memory bank in response to the second control signal, to transmit data in the second memory circuit to the target memory bank. The memory bank coupled to the damaged word line is different from the target memory bank coupled to the redundant word line corresponding to the damaged word line.

In some examples, the plurality of second memory circuits are configured to be coupled to at least one redundant word line or at least one word line in response to the plurality of first control signals, respectively.

In some examples, the second memory circuit comprises a content addressable memory cell.

In some examples, the content addressable memory cell comprises a second memory element and a comparison circuit. The second memory element is configured to store identification information and address information of the damaged word line acquired from the first memory circuit, and identification information and address information of the redundant word line corresponding to the damaged word line. The comparison circuit is configured to compare user data with the address information of the damaged word line stored in the second memory element, and when the user data is the same as the address information of the damaged word line, the redundant word line corresponding to the damaged word line is coupled.

In some examples, the second memory element further stores address information of the memory bank coupled to the damaged word line and address information of the memory bank coupled to the redundant word line corresponding to the damaged word line. The address information of the memory bank coupled to the word line is different from the address information of the memory bank coupled to the redundant word line.

In some examples, the first memory circuit comprises a one-time programmable memory cell. The one-time programmable memory cell comprises a first memory element and at least one transistor, wherein the first memory element stores the address information of the damaged word line.

In some examples, the damaged word line is coupled to the second memory circuit. The redundant word line is coupled to the memory bank and the second memory circuit. One redundant word line corresponds to one damaged word line. A plurality of redundant word lines are sequentially adjacent, and the plurality of redundant word lines coupled to one of the memory banks are disposed on a side of the memory bank.

In some examples, the peripheral circuit further comprises a buffer circuit. The buffer circuit is coupled to the plurality of second memory circuits, the first memory circuit and a data transmission interface, and is configured to transmit user data transmitted by the data transmission interface to the second memory circuits in response to a third control signal, and is further configured to transfer data in the first memory circuit to the plurality of second memory circuits in response to a fourth control signal.

In some examples, the buffer circuit comprises a buffer and a second multiplexer circuit coupled to the buffer. A first input of the second multiplexer circuit is coupled to the data transmission interface, a second input of the second multiplexer circuit is coupled to the first memory circuit, and an output of the second multiplexer circuit is coupled to the plurality of second memory circuits through the buffer.

In some examples, the peripheral circuit further comprises an input/output circuit. The input/output circuit is coupled to the data transmission interface and is configured to receive user data and output it to the data transmission interface.

In the above memory device, the second memory circuit can disconnect the connection with the damaged word line in response to the first control signal, and then realize the connection with the redundant word line corresponding to the damaged word line, and can transmit the data in the second memory circuit to the memory bank. Considering that the first memory circuit and the second memory circuit transmit a large amount of data, and there is a large difference in the lengths of the data transmission paths between different second memory circuits and the first memory circuit, it is easy to cause the data transmission to be delayed. By adjusting the layout position relationship between the plurality of second memory circuits and the first memory circuit in the memory device, the data transmission paths between the plurality of second memory circuits and the first memory circuit are all set to be shorter than the data transmission paths between the plurality of second memory circuits and the plurality of memory banks. As such, not only the delay of transmitting data from the first memory circuit to the different second memory circuits can be reduced, but also the flexible adjustment of the layout of lines between the second memory circuits and the memory banks are facilitated, which is beneficial to reducing the process cost and the product size.

According to a second aspect, implementations of the present disclosure provide a memory system. The memory system includes a memory device and a memory controller. The memory device comprises a first memory circuit and a second memory circuit. The memory controller is coupled to the memory device, is configured to transfer address information of a damaged word line stored in the first memory circuit to the second memory circuit, and transmit user data to the second memory circuit, and is further configured to output a first control signal to instruct the second memory circuit to couple to a redundant word line corresponding to the damaged word line when the user data is the same as the address information of the damaged word line after comparison.

In some examples, the memory device further comprises a first multiplexer circuit. The memory controller is further configured to output a second control signal instructing the first multiplexer circuit to transmit data in the second memory circuit to a target memory bank coupled to the redundant word line. The memory bank coupled to the damaged word line is different from the target memory bank coupled to the redundant word line corresponding to the damaged word line.

The above memory system comprises the memory device provided by any one of the above examples. The beneficial effects of the memory system are the same as those of the memory device provided in any one of the above examples, and details are not described herein again.

According to a third aspect, implementations of the present disclosure provide a driving method of a memory device. The driving method comprises transferring address information of a damaged word line of word lines coupled with a plurality of memory banks stored in a first memory circuit into a second memory circuit in response to a power-on reset signal; in response to a first control signal, comparing user data with data stored in the second memory circuit, and determining and coupling to a redundant word line corresponding to the damaged word line, wherein a data transmission path between the second memory circuit and the first memory circuit is shorter than a transmission path from the second memory circuit to the memory banks through the coupled redundant word line.

In some examples, the determining and coupling to the redundant word line corresponding to the damaged word line comprises: according to the address information and identification information of the damaged word line, determining identification information and address information of the redundant word line corresponding to the damaged word line, and determining a target redundant word line; determining a target memory bank according to address information of the memory bank coupled to the target redundant word line, wherein the memory bank coupled to the damaged word line is different from the target memory bank; and coupling the second memory circuit and the target memory bank through the target redundant word line.

In some examples, the determining and coupling to the redundant word line corresponding to the damaged word line comprises: according to the address information and identification information of the damaged word line, determining identification information and address information of the redundant word line corresponding to the damaged word line and address information of the memory bank coupled to the redundant word line, and determining a target redundant word line; and coupling the second memory circuit and the target memory bank through the target redundant word line.

In some examples, the method further comprises: coupling a target redundant word line with a target memory bank in response to a second control signal, to transmit data in the second memory circuit to the target memory bank. The memory bank coupled to the word line is different from the target memory bank coupled to the target redundant word line.

In some examples, the transmitting the data in the second memory circuit to the target memory bank comprises: after decoding the data transmitted by the redundant word line, transmitting it to the target memory bank.

In some examples, the method further comprises transmitting the user data to the second memory circuit in response to a third control signal; and transferring data in the first memory circuit to a plurality of second memory circuits in response to a fourth control signal.

In some examples, the method further comprises updating the address information of the damaged word line stored in the first memory circuit in response to a refresh signal.

The above driving method is configured to drive the memory device provided by any one of the above examples. The beneficial effects of the driving method of a memory device is the same as those of the memory device provided in any one of the above examples, and details are not described herein again.

The foregoing is only an implementation of the present disclosure, but the protection scope of the present disclosure is not limited thereto, and any changes or replacements that can be easily conceived by those skilled in the art within the technical scope disclosed in the present disclosure should be covered within the protection scope of the present disclosure. Therefore, the protection scope of the present disclosure should be subject to the protection scope of the following claims.

What is claimed is:

1. A memory device, comprising:
a memory cell array comprising a plurality of memory banks;
a peripheral circuit coupled to the plurality of memory banks, the peripheral circuit comprising:
a first memory circuit configured to store address information of a damaged word line of a plurality of word lines, the word lines coupled with the plurality of memory banks; and
a plurality of second memory circuits coupled with the first memory circuit, wherein one of the plurality of second memory circuits is configured to couple to a redundant word line corresponding to the damaged word line in response to a first control signal, wherein data transmission paths between the plurality of second memory circuits and the first memory circuit are shorter than data transmission paths between the plurality of second memory circuits and the plurality of memory banks.

2. The memory device of claim 1, wherein the peripheral circuit further comprises a first multiplexer circuit, wherein:
a plurality of inputs of the first multiplexer circuit are respectively coupled to the plurality of second memory circuits, and an output of the first multiplexer circuit is coupled to a memory bank of the plurality of memory banks;
the first multiplexer circuit is configured to couple the redundant word line corresponding to the damaged word line with a target memory bank in response to a second control signal, to transmit data in at least one of the second memory circuits to the target memory bank; and
the memory bank coupled to the damaged word line is different from the target memory bank coupled to the redundant word line corresponding to the damaged word line.

3. The memory device of claim 2, wherein the plurality of second memory circuits are configured to couple to at least one redundant word line or at least one word line in response to a plurality of first control signals.

4. The memory device of claim 1, wherein at least one of the second memory circuits comprises a content addressable memory cell.

5. The memory device of claim 4, wherein:
the content addressable memory cell comprises a second memory element and a comparison circuit;
the second memory element is configured to store identification information and address information of the damaged word line acquired from the first memory circuit, and identification information and address information of the redundant word line corresponding to the damaged word line; and
the comparison circuit is configured to compare user data with the address information of the damaged word line stored in the second memory element, and when the user data is the same as the address information of the damaged word line, the redundant word line corresponding to the damaged word line is coupled to the one of the plurality of second memory circuits.

6. The memory device of claim 5, wherein the second memory element further stores address information of a first one of the memory banks coupled to the damaged word line and address information of a second one of the memory banks coupled to the redundant word line corresponding to the damaged word line; and
the address information of the first memory bank coupled to the damaged word line is different from the address information of the second memory bank coupled to the redundant word line.

7. The memory device of claim 1, wherein:
the first memory circuit comprises a one-time programmable memory cell; and
the one-time programmable memory cell comprises a first memory element and at least one transistor, wherein the first memory element stores the address information of the damaged word line.

8. The memory device of claim 1, wherein:
the word lines are coupled to the second memory circuits;
a plurality of redundant word lines are coupled to the memory banks and the second memory circuits;
one of the redundant word lines corresponds to one damaged word line of the word lines;
the plurality of redundant word lines are sequentially adjacent; and
the plurality of redundant word lines coupled to a memory bank of the memory banks are disposed on a side of the memory bank.

9. The memory device of claim 1, wherein the peripheral circuit further comprises:
a buffer circuit coupled to the plurality of second memory circuits, the first memory circuit and a data transmission interface, and configured to transmit user data transmitted by the data transmission interface to at least one of the second memory circuits in response to a third control signal, and further configured to transfer data in the first memory circuit to the plurality of second memory circuits in response to a fourth control signal.

10. The memory device of claim 9, wherein:
the buffer circuit comprises a buffer and a second multiplexer circuit coupled to the buffer;
a first input of the second multiplexer circuit is coupled to the data transmission interface;
a second input of the second multiplexer circuit is coupled to the first memory circuit; and
an output of the second multiplexer circuit is coupled to the plurality of second memory circuits through the buffer.

11. The memory device of claim 1, wherein the peripheral circuit further comprises:
an input/output circuit coupled to a data transmission interface and configured to receive user data and output it to the data transmission interface.

12. A memory system, comprising:
a memory device comprising a first memory circuit and a second memory circuit; and
a memory controller coupled to the memory device, the memory controller configured to:
transfer address information of a damaged word line stored in the first memory circuit to the second memory circuit;
transmit user data to the second memory circuit; and
output a first control signal to instruct the second memory circuit to couple to a redundant word line corresponding to the damaged word line when the user data is the same as the address information of the damaged word line.

13. The memory system of claim 12, wherein:
the memory device further comprises a first multiplexer circuit;
the memory controller is further configured to output a second control signal to instruct the first multiplexer circuit to transmit data in the second memory circuit to a target memory bank coupled to the redundant word line; and
a memory bank coupled to the damaged word line is different from the target memory bank coupled to the redundant word line corresponding to the damaged word line.

14. A driving method of a memory device, comprising:
transferring address information of a damaged word line of a plurality of word lines to a second memory circuit in response to a power-on reset signal, the word lines coupled with a plurality of memory banks stored in a first memory circuit; and
in response to a first control signal, comparing user data with data stored in the second memory circuit, and coupling the second memory circuit to a redundant word line corresponding to the damaged word line,
wherein a data transmission path between the second memory circuit and the first memory circuit is shorter than a transmission path from the second memory circuit to the memory banks through the redundant word line.

15. The driving method of claim 14, further comprising:
based on the address information and identification information of the damaged word line, determining identification information and address information of the redundant word line, and determining the redundant word line; and
determining a target memory bank based on address information of a first one of the memory banks coupled to the redundant word line, wherein a second one of the memory banks coupled to the damaged word line is different from the target memory bank, wherein the coupling of the second memory circuit to the redundant word line comprises:
coupling the second memory circuit to the target memory bank through the redundant word line.

16. The driving method of claim 14, further comprising:
based on the address information and identification information of the damaged word line, determining identification information and address information of the redundant word line corresponding to the damaged word line and address information of a memory bank coupled to the redundant word line, and determining the redundant word line, wherein the coupling of the second memory circuit to the redundant word line comprises:
coupling the second memory circuit to the memory bank through the redundant word line.

17. The driving method of claim 14, further comprising:
coupling the redundant word line with a target memory bank in response to a second control signal; and
transmitting data in the second memory circuit to the target memory bank, wherein a memory bank coupled to the damaged word line is different from the target memory bank coupled to the redundant word line.

18. The driving method of claim 17, wherein the transmitting of the data in the second memory circuit to the target memory bank comprises:
after decoding the data transmitted by the redundant word line, transmitting the data to the target memory bank.

19. The driving method of claim 14, further comprising:
transmitting the user data to the second memory circuit in response to a third control signal; and
transferring data in the first memory circuit to a plurality of second memory circuits in response to a fourth control signal.

20. The driving method of claim 14, comprising:
updating the address information of the damaged word line stored in the first memory circuit in response to a refresh signal.
